(19) United States
(12) Patent Application Publication
(10) Pub. No.: US 2025/0333626 A1
(43) Pub. Date: Oct. 30, 2025

(54) ADHESIVE RESIN MIXTURE AND SELF-ASSEMBLING ANISOTROPIC CONDUCTIVE ADHESIVE HAVING CONTROLLED FLUIDITY

(71) Applicant: NOPION CO., LTD., Suwon-si, Gyeonggi-do (KR)

(72) Inventors: Chang Hoon SIM, Seoul (KR); Kyung Sub LEE, Yongin-si, Gyeonggi-do (KR)

(21) Appl. No.: 18/725,416

(22) PCT Filed: Dec. 28, 2022
(86) PCT No.: PCT/KR2022/021555

§ 371 Date: Jun. 28, 2024

(30) Foreign Application Priority Data
Dec. 28, 2021 (KR) 10-2021-0190253

(51) Int. Cl. C09J 9/02; C09J 7/35; C09J 11/04; C09J 163/04

(52) U.S. Cl. CPC C09J 9/02; C09J 7/35; C09J 11/04; C09J 163/04; C09J 2301/304; C09J 2301/408

(57) ABSTRACT

An embodiment provides an adhesive resin mixture having controlled fluidity, and a self-assembling anisotropic conductive adhesive comprising the adhesive resin mixture. The self-assembling anisotropic conductive adhesive comprising the adhesive resin mixture having controlled fluidity provides excellent contact resistance while also providing superior adhesion compared to that provided by conventional adhesives.

### TECHNICAL FIELD

The present invention relates to a self-assembling anisotropic conductive adhesive, and more particularly, to a self-assembling anisotropic conductive adhesive having controlled fluidity.

### BACKGROUND ART

Entering the 21st century, where materials required in each engineering field or materials with required surface characteristics are being made, semiconductor packages are becoming more highly integrated, more high-performance, less costly, and more miniaturized as information and communication devices advance. In addition, flexible displays, which have recently been attracting attention as next-generation displays, have excellent bendability and may be folded or rolled, so that research on stable electrical/mechanical characteristics and high integration of mounted microcomponents is rapidly progressing.

Accordingly, the development of high-density electronic packaging technology is actively underway, and among these electronic packaging technologies, the bonding method using anisotropic conductive adhesives (ACAs) has great advantages such as low-temperature processes and simplified processes.

The anisotropic conductive adhesive is a material made by mixing metal powder or conductive polymer powder into a polymer binder, and it has the electrical, magnetic, and optical properties of metal as well as the mechanical properties and processability of polymer, and is a key material that is essential for connecting drive ICs to display panel glass and flexible PCBs.

Such anisotropic conductive adhesive generally includes solder particles, a reducing agent, and an adhesive resin. As seen from FIGS. 1 to 3, after the component mounting process, the solder particles 31 in the anisotropic conductive adhesive 30 are positioned between the metal terminals of the substrate, and the solder particles serve as an electrical passage, while the adhesive resin 32 in the anisotropic conductive adhesive serves as an adhesive.

However, when the component mounting process is performed, the adhesive resin has fluidity, so that there are cases where the adhesive resin and the solder particles are positioned between the metal terminals of the substrate; however, if the viscosity of the adhesive resin is too low, there is a problem that both the solder particles and the adhesive resin leak out between the metal terminals of the substrate and are lost, weakening the adhesion. On the other hand, if the viscosity of the adhesive resin is too high, the fluidity of the adhesive resin and the solder particles is inhibited, and when the component mounting process is performed, the adhesive resin and the solder particles are not positioned between the metal terminals of the substrate, which also causes a problem.

Accordingly, a self-assembling anisotropic conductive adhesive having an appropriate viscosity to properly position an adhesive resin and solder particles between metal terminals of a substrate and further having appropriate fluidity to prevent the solder particles and adhesive resin from leaking when performing the component mounting process is required.

### RELATED ART DOCUMENT

Republic of Korea Patent Publication No. 10-2062482

### DETAILED DESCRIPTION OF THE INVENTION

### Technical Problem

An aspect of the present invention is to provide a self-assembling anisotropic conductive adhesive including an adhesive resin of which fluidity is controlled within an appropriate range.

In addition, an aspect of the present invention is to provide a self-assembling anisotropic conductive adhesive having excellent adhesion and low contact resistance.

The aspect of the present invention is not limited to that mentioned above, and other aspects not mentioned will be clearly understood by those skilled in the art from the description below.

### Technical Solution

An embodiment of the present invention provides a self-assembling anisotropic conductive adhesion adhesive resin mixture, including: a first epoxy resin including a plurality of epoxy groups in a molecule; and a second epoxy resin having a viscosity of 100 cps or more and 500 cps or less.

In an embodiment of the present invention, a weight ratio of the first epoxy resin and the second epoxy resin may be 1:1.2 or more and 1:1.5 or less.

In addition, in an embodiment of the present invention, the adhesive resin mixture may have a viscosity of 500 cps or more and 100,000 cps or less in a temperature range of 70° C. or more and 250° C. or less.

In addition, in an embodiment of the present invention, the first epoxy resin may be one selected from the group consisting of a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin.

In addition, in an embodiment of the present invention, the first epoxy resin may have a weight average molecular weight (Mw) of 30,000 or more and 60,000 or less.

In addition, in an embodiment of the present invention, the second epoxy resin may be one selected from the group consisting of a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin.

In addition, in an embodiment of the present invention, the second epoxy resin may have an epoxy equivalent of 10 g/ep or more and 200 g/ep or less.

Another embodiment of the present invention provides a self-assembling anisotropic conductive adhesive having controlled fluidity, including: conductive solder particles; and the adhesive resin mixture of claim 1, wherein by having the adhesive resin mixture of claim 1 to have a viscosity of 500 cps or more and 100,000 cps or less in a temperature range of 70° C. or more and 250° C. or less, the solder particles and the adhesive resin mixture are positioned maximally between metal terminals of a substrate during a component mounting process.

In an embodiment of the present invention, the solder particles may have a melting point between a reaction initiation temperature and a hardening temperature of the conductive adhesive resin mixture.

In addition, in an embodiment of the present invention, the solder particles may include at least one selected from the group consisting of tin (Sn), copper (Cu), indium (In), silver (Ag), and bismuth (Bi).

In addition, in an embodiment of the present invention, the solder particles may have a melting point of 70° C. or more and 250° C. or less.

In addition, in an embodiment of the present invention, the anisotropic conductive adhesive may be in the form of a film or paste.

### Advantageous Effects

According to an embodiment of the present invention, a self-assembling anisotropic conductive adhesive may be provided, which includes an adhesive resin of which fluidity is controlled to an appropriate range, so that the adhesive resin and solder particles are maximally positioned between metal terminals of a substrate in a component mounting process step, and a self-assembling anisotropic conductive adhesive having excellent adhesion and low contact resistance may be provided.

The effects of the present invention are not limited to the effects described above, and should be understood to include all effects that are inferable from the configuration of the present invention described in the detailed description or claims of the present invention.

### BRIEF DESCRIPTION OF THE DRAWINGS

FIG. 1 is a functional block diagram of a physical quantity image data analysis device 1 according to an embodiment of the present invention.

FIG. 2 FIG. 1 is a view showing the state of a conductive adhesive positioned between substrates before a self-assembling anisotropic conductive adhesive is hardened.

FIG. 2 is a view showing a process in which an adhesive resin and solder particles are hardened in a step in which a self-assembling anisotropic conductive adhesive is mounted.

FIG. 3 is a view showing a connector positioned between substrates after a self-assembling anisotropic conductor is hardened,

FIG. 4 is a view showing the state of a conductive adhesive positioned between substrates before a self-assembling anisotropic conductor provided by an embodiment of the present invention is hardened.

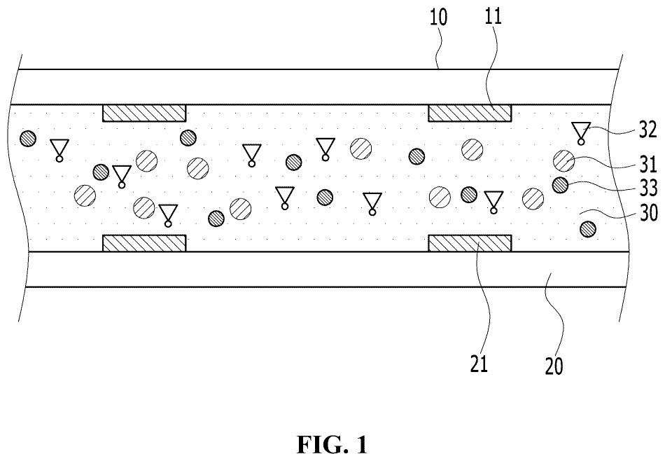

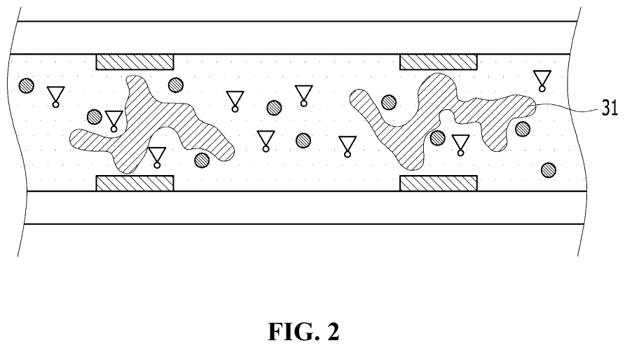

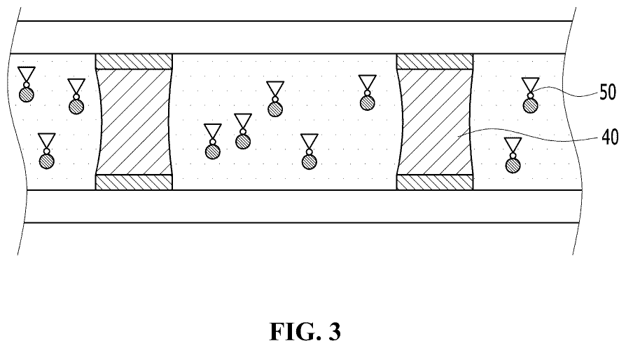

### MODE FOR CARRYING OUT THE INVENTION

Hereinafter, the present invention will be described with reference to the accompanying drawings. However, the present invention may be implemented in various different forms and, therefore, is not limited to the examples described herein. In order to clearly explain the present invention in the drawings, portions unrelated to the description are omitted, and similar portions are given similar reference numerals throughout the specification.

Throughout the specification, when a portion is said to be “connected (linked, contacted, combined)” with another portion, this includes not only a case of being “directly connected” but also a case of being “indirectly connected” with another member in between. In addition, when a portion is said to “include” a certain component, this does not mean that other components are excluded, but that other components may be added, unless specifically stated to the contrary.

The terms used herein are merely used to describe specific embodiments and are not intended to limit the present invention. Singular expressions include plural expressions unless the context clearly dictates otherwise. In this specification, it should be understood terms such as “include” or “have” are to designate the presence of features, numbers, steps, operations, components, parts, or combinations thereof described in the specification, but are not to exclude in advance the possibility of the presence or addition of one or more other features, numbers, steps, operations, components, parts, or combinations thereof.

Hereinafter, a self-assembling anisotropic conductive adhesive 30 having controlled fluidity according to an embodiment of the present invention will be described in detail with reference to the accompanying drawings.

According to an embodiment of the present invention, provided is a self-assembling anisotropic conductive adhesive 30 (hereinafter, referred to as “SACA”) having controlled fluidity, including: conductive solder particles 31; and an adhesive resin mixture to be described later, wherein by including the adhesive resin mixture to have a viscosity of 500 cps or more and 100,000 cps or less in a temperature range of 70° C. or more and 250° C. or less, there is an effect of maximally positioning the solder particles and the adhesive resin mixture 32 between metal terminals 11 of a substrate in a component mounting process.

In the component mounting process step, the adhesive resin 32 in the adhesive resin mixture included in the SACA 30 has fluidity and is positioned between the metal terminals of the substrate, and the metal terminals of the substrate are bonded as the adhesive resin in the SACA 30 hardens.

At this time, the adhesive resin 32 having the fluidity must have a fluidity within an appropriate numerical range, and if the fluidity is too low, the fluidity of the adhesive resin 32 and the solder particle 31 is inhibited, and thus the adhesive resin may not be positioned between the metal terminals 21 of the substrate in the first place. On the contrary, if the fluidity is too high, in the step of applying heat and pressure to pressurize, the adhesive resin 32 and the solder particles 31 are separated from the metal terminals 21 of the substrates 10, 20 due to the excessively high fluidity, and ultimately, the adhesion between the substrates 10, 20 does not occur, and the stability and reliability of the product are lowered.

Accordingly, as described above, in an embodiment of the present invention, an SACA 30 is provided to increase the adhesion of the substrate by controlling the fluidity of the adhesive resin 32.

Hereinafter, the adhesive resin 32 of the SACA 30 with controlled fluidity will be described.

In the present invention, the adhesive resin 32 of the SACA 30 with the fluidity controlled mainly uses the adhesive resin mixture for the SACA of the embodiment described below, but the adhesive resin is not limited to the adhesive resin mixture for the SACA described below, and it should be interpreted that the mixture identical or equivalent to the adhesive resin mixture provided in one embodiment of the present invention and the adhesive resin providing the same or equivalent effect are all within the scope of the present invention.

Hereinafter, the solder particles of the SACA (30) with the fluidity controlled will be described.

Hereinafter, the role of the solder particles is described.

The solder particles used in the present invention may use conductive particles, and by using the conductive particles, the solder particles are ultimately positioned between the substrates and serve as an electrical passage between the electrodes of the substrates.

Hereinafter, the melting point of the solder particles will be described.

When heating electronic components in the mounting process, the solder particles need to melt first to create a connector before the thermosetting resin hardens, and the viscosity of the thermosetting resin needs to be reduced so that the melted solder particles may coagulate smoothly in the heated state; therefore, it is desirable that the melting point of the solder particles be between the reaction initiation temperature and the hardening completion temperature of the thermosetting resin.

Accordingly, the solder particles may be low-melting-point solder particles having a melting point of 70° C. or more and 250° C. or less. By using low-melting-point solder particles likewise, it is possible to suppress or prevent various parts of electronic components from being damaged by thermal history.

Hereinafter, the composition of the solder particles is described.

In addition, the solder particles may include two or more from the group consisting of tin (Sn), indium (In), copper (Cu), silver (Ag), and bismuth (Bi). For example, the solder particles may include, but are not limited to, 60Sn/40Bi, 52In/48Sn, 97 In/3Ag, 57Bi/42Sn/1Ag, 58Bi/42Sn, and 96.5Sn/3.5Ag. However, the particles are not limited to the metal particles, and it should be interpreted that all configurations that may be easily modified and adopted by a person with ordinary knowledge in the same technical field to achieve the effects of the present invention, such as conjugated polymers and conductive polymers, are all included in this right.

In addition, if the solder particles are metal elements, they easily form an oxide film on the surface by coming into contact with oxygen in the atmosphere. Due to the formed oxide film, when mounting electronic components such as semiconductor chips using an anisotropic conductive adhesive containing solder particles, there is a problem that unstable electrical characteristics such as low conductivity and unstable bonding strength occur due to unstable contact resistance. As a method for solving this, in a step of mixing and dispersing the solder particles and the binder resin, solder particles with improved wetting through a reducing agent such as carboxylic acid may be used to strengthen the bonding with the wiring and signal line contacts.

That is, if the solder particles are metal elements, they may form an oxide film, and it is preferable that the oxide film of the solder particles is removed or controlled through a reducing agent.

Hereinafter, the particle size of the solder particles is described.

The size of the solder particles may be selected according to the size of the applied conductive pattern (e.g. pitch), and as the size of the conductive pattern increases, solder particles with a larger particle size may be used.

Hereinafter, the mixing ratio of the solder particles is described.

The solder particles may be contained in a ratio of 5 to 60 volume % with respect to the total amount of SACA (30) of which fluidity is controlled in consideration of fluidity and wetting characteristics. If less than 5% by volume, there is a risk that the solder particles will be insufficient and that the terminals will not be connected, and if more than 60% by volume, there is a risk that the solder particles will remain excessively and cause a bridge between adjacent terminals by the connector, resulting in a short circuit.

Hereinafter, the physical properties and characteristics of the SACA 30 with the fluidity controlled are described.

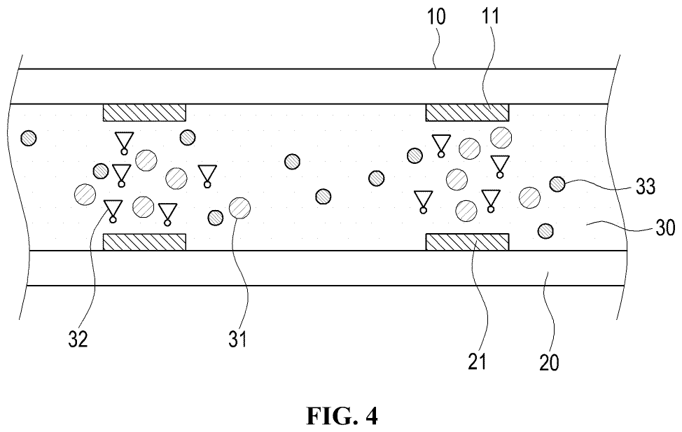

FIG. 4 is a view showing the state of a conductive adhesive positioned between substrates before a self-assembling anisotropic conductor provided by an embodiment of the present invention is hardened.

As described above, the SACA 30 with controlled fluidity is preferably to have a viscosity of 500 cps or more and 100,000 cps or less in a temperature range of 70° C. or more and 250° C. or less.

As described above, in the component mounting process step, the solder particles and adhesive resin should be positioned between metal terminals of a substrate as shown in FIG. 4. If the viscosity of the adhesive resin is less than 500 cps, the viscosity of the adhesive resin becomes excessively low and the fluidity increases, and accordingly, in the component mounting process step, both the solder particles and adhesive resin leak out between the metal terminals of the substrate and are lost, weakening the adhesion of the final product. On the other hand, if the viscosity of the adhesive resin exceeds 100,000 cps, the viscosity of the adhesive resin becomes excessively high and the fluidity decreases, and accordingly, the solder particles and the adhesive resin are not positioned between the metal terminals of the substrate during the component mounting process, which weakens the adhesion of the final product; therefore, it is preferable that the anisotropic conductive adhesive have a viscosity of 500 cps or more and 100,000 cps or less in a temperature range of 70° C. or more and 250° C. or less.

In addition, the SACA 30 with controlled fluidity may be used in a film form or a paste form. However, in the mounting of the substrate, the film form is superior to the paste form in terms of quality control such as electronic component mounting costs, thickness control, and adhesion reliability, so that it is preferable to use a film-type conductive adhesive.

In addition, as seen through the experiments described below, the SACA 30 with controlled fluidity has adhesion of 2.0 to 3.0 kgf/cm and, at the same time, excellent contact resistance, and thus has a high possibility of being used as a mounting conductive adhesive in various industrial fields such as substrates, displays, and semiconductors, compared to the anisotropic conductive adhesive previously presented.

Hereinafter, an adhesive resin mixture for an SACA provided by another embodiment of the present invention will be described.

Another embodiment of the present invention provides an adhesive resin mixture for an SACA, including: a first epoxy resin including multiple epoxy groups in the molecule; and a second epoxy resin having a viscosity of 100 cps or more and 500 cps or less at 20° C. or more and 30° C. or less.

In addition, the adhesive resin mixture for the SACA must perform the function of ensuring that the solder particles and the adhesive resin are appropriately positioned between the metal terminals of the substrate in the component mounting process as described above, and therefore, it is preferable that the adhesive resin mixture for the SACA have a viscosity of 500 cps or more and 100,000 cps or less in a temperature range of 70° C. or more and 250° C. or less, which is the melting temperature of the solder particles.

Hereinafter, the constituent compounds of the adhesive resin will be described.

The adhesive resin may include an adhesive resin mixture that mixes multiple epoxy resins, and the adhesive resin mixture may include: a first epoxy resin that includes multiple epoxy groups in the molecule; and a second epoxy resin having an epoxy equivalent of 10 g/ep or more and 200 g/ep or less.

In the present specification, “epoxy equivalent” means the molecular weight (g/eqiv) for one epoxy group (meaning the value obtained by dividing the average molecular weight by the number of epoxy groups per molecule), and therefore, when the average molecular weight is fixed, the equivalent weight decreases as the number of epoxy groups per molecule increases, and the equivalent weight increases as the number decreases.

At this time, the first epoxy resin includes multiple epoxy groups in the molecule, and the second epoxy resin has a viscosity of 100 cps or more and 500 cps or less at 20° C. or more and 30° C. or less, and preferably has a viscosity of 100 cps or more and 500 cps or less at room temperature of 25° C., so that the viscosity, self-assembly, and physical properties of the composition may be controlled.

In addition, at this time, the weight ratio of the first epoxy resin and the second epoxy resin may be 1:1 or more and 1:2 or less, and preferably 1:1.2 or more and 1:1.5 or less. If the mixing ratio of the first epoxy resin and the second epoxy resin is less than 1:1 and the first epoxy resin is excessively added, the viscosity value becomes excessively high (exceeding the viscosity range provided), which causes a problem in that self-assembly is not easy, and if the mixing ratio exceeds 1:2 and the second epoxy resin is excessively added, the problem in that the properties described above are not secured occurs. Therefore, in order to prevent the above-described problem from occurring, the mixing ratio of the first epoxy resin and the second epoxy resin may be 1:1 or more and 1:2 or less, and in order to obtain the best effect, the mixing ratio may be preferably 1:1.2 or more and 1:1.15 or less.

Hereinafter, the first epoxy resin will be described.

It is preferable to use the first epoxy resin that has epoxy groups attached to both side chains, so that it is possible to secure the characteristics of the epoxy groups, such as high adhesion, chemical resistance, moisture absorption resistance, and high insulation.

In addition, the first epoxy resin may be one selected from the group including, for example, a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin, but is not limited thereto.

When mixing the first epoxy resin, the mixing amount may be determined based on the weight ratio, wherein the weight ratio is the weight average molecular weight, and the weight average molecular weight (Mw) of the first epoxy resin to be mixed may be characterized as being 30,000 or more and 60,000 or less.

If the weight average molecular weight of the first epoxy resin is less than 30,000, the problem of the final hardened product having excessive brittleness occurs due to low toughness.

On the other hand, the larger the weight average molecular weight is, the lower the maximum crosslinking density achievable by the reaction of the epoxy group is, and the heat resistance tends to decrease; therefore, if the weight average molecular weight of the first epoxy resin exceeds 60,000, the maximum crosslinking density achievable by the reaction of the epoxy group is lowered, which causes a problem in that the final degree of hardening is lowered, and the heat resistance is reduced, which causes a problem in that the physical properties are not stable after hardening.

In addition, it is preferable that the first epoxy resin use an epoxy resin having a softening point of 130° C. or more and 150° C. or less. When using the first epoxy resin having a softening point in the above temperature range, high heat resistance may be secured.

When the composition is composed only of epoxy resins with low viscosity or softening point for securing fluidity during SACA bonding or for other purposes, fluidity control becomes very easy, but the heat resistance is low, so that the physical properties after hardening may not be stable,

Hereinafter, the second epoxy resin will be described.

When the first epoxy resin is used alone, the viscosity value is excessively high at all temperatures of 70° C. or more and 250° C. or less and the melting temperature of the solder where self-assembly occurs, making self-assembly of the adhesive resin mixture difficult; therefore, it is necessary to lower the viscosity of the adhesive resin mixture for the SACA to facilitate self-assembly, and the second epoxy resin is included for the purpose above.

In addition, the second epoxy resin should act as a diluent that lowers the viscosity of the adhesive resin mixture for the SACA, while not impairing the overall properties of the adhesive resin mixture for SACA, thereby ensuring high reliability after hardening of the adhesive resin mixture for SACA; therefore, it is preferable to use an epoxy resin with high heat resistance and glass transition temperature.

The second epoxy resin may be one selected from the group including a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin, but is not of course limited thereto.

At this time, the second epoxy resin may be used having an epoxy equivalent of 10 g/ep or more and 200 g/ep or less, wherein if the epoxy equivalent is less than 10 g/ep, the number of reactive epoxy groups is too large, causing problems in that unreacted ones remain and impurities are generated, and on the other hand, if the epoxy equivalent exceeds 200 g/ep, the number of reactive epoxy groups is too small; therefore, it is most preferable that the epoxy equivalent is 10 g/ep or more and 200 g/ep or less.

Hereinafter, the present invention is described in more detail through Production Examples, Comparative Examples, and Experimental Examples. However, the present invention is not limited to Production Examples and Experimental Examples below.

### Production Example 1—Production of Adhesive Resin Mixture for SACA

In this Production Example 1, a phenol novolac epoxy resin was mixed as a first epoxy resin, and bisphenol F epoxy resin was mixed as a second epoxy resin to produce several adhesive resin mixtures. The specific production process is as follows.

A phenol novolac epoxy resin having a weight average molecular weight (Mw) of 50,000 and a bisphenol F epoxy resin having a weight average molecular weight (Mw) of 40,000 were mixed in a weight ratio of 1:0.1, 1:1.1, . . . , 1:1.9, 1:2.0 to prepare 20 adhesive resin mixtures for SACAs, and mixing was performed at 30° C. for 30 minutes.

Table 1 below summarizes the above ratios.

TABLE 1

| | First epoxy resin | Second epoxy resin |
|---|---|---|
| | Phenol novolac | Bisphenol F |
| Entry | epoxy resin | epoxy resin |
| 1 | 1 | 0.1 |
| 2 | 1 | 0.2 |
| 3 | 1 | 0.3 |
| 4 | 1 | 0.4 |
| 5 | 1 | 0.5 |
| 6 | 1 | 0.6 |
| 7 | 1 | 0.7 |
| 8 | 1 | 0.8 |
| 9 | 1 | 0.9 |
| 10 | 1 | 1.0 |
| 11 | 1 | 1.1 |
| 12 | 1 | 1.2 |
| 13 | 1 | 1.3 |
| 14 | 1 | 1.4 |
| 15 | 1 | 1.5 |
| 16 | 1 | 1.6 |
| 17 | 1 | 1.7 |
| 18 | 1 | 1.8 |
| 19 | 1 | 1.9 |
| 20 | 1 | 2.0 |

In Production Example 1 seen through the process above, an adhesive resin mixture was successfully produced.

### Production Example 2—Production of SACA With Controlled Fluidity

In Production Example 2, a self-assembling anisotropic conductive adhesive including the adhesive resin mixture produced in Production Example 1 and solder particles including Bi and In metals was produced. The specific production process is as follows.

An SACA was produced by mixing the adhesive resin mixture (50 wt %) of entry 1 to entry 20 of Table 1 produced in Production Example 1, solder particles (30 wt %), a reducing agent (5 wt %), a hardening agent (10 wt %), and a silane coupling agent (5 wt %).

At this time, the first epoxy resin and the second epoxy resin were mixed at 30° C. for 30 minutes to form a mixture, and a process of mixing other additives with the mixture at 25° C. for 10 minutes was performed.

Thereafter, a process of mixing pretreated solder particles and a reducing agent with the mixture at 25° C. for 10 minutes was performed, and finally, a process of mixing a hardening agent with the mixture at 25° C. for 1 minute was performed.

At this time, all of the mixing processes were performed using a paste mixer.

As a result, a self-assembling anisotropic conductive adhesive was successfully produced.

### Production Example 3—Production of SACA With Controlled Fluidity With Different Solder Particle Compositions

In this Production Example 3, the Bi and In metals, which are components of the solder particles, in the Production Example 2, were changed to Sn, Ag, and Cu metals with a capacity of 30 wt %, and various SACAs were produced using the same method.

It was possible to produced SACAs containing various solder particles by changing the metal elements. Through this, it is possible to see that anisotropic conductive adhesives containing metal elements desired by a user may be produced.

### Experimental Example 1—Confirmation of Viscosity of Adhesive Resin Mixture

In this Experimental Example 1, the viscosity of the adhesive resin mixture produced in Production Example 1 was measured.

The specific experimental method is as follows.

The experiment was conducted by measuring the lowest viscosity value in a temperature range of 70° C. to 250° C. using a rheometer.

TABLE 2

| Entry | Viscosity |
|---|---|
| 1 | 140,000 |
| 2 | 130,000 |
| 3 | 120,000 |
| 4 | 110,000 |
| 5 | 100,000 |
| 6 | 95,000 |
| 7 | 85,000 |
| 8 | 75,000 |
| 9 | 65,000 |
| 10 | 55,000 |
| 11 | 50,000 |
| 12 | 45,000 |
| 13 | 40,000 |
| 14 | 35,000 |
| 15 | 30,000 |
| 16 | 25,000 |
| 17 | 20,000 |
| 18 | 10,000 |
| 19 | 5,000 |
| 20 | 500 |

As seen from Table 2 above, the closer the mixing ratio of bisphenol F epoxy and phenol novolac epoxy is to 1:1, the higher the viscosity is, and the closer that is to 1:2, the lower the viscosity is. In addition, as seen from Experimental Examples described below, the adhesive resin mixture produced in Production Example 1 is the most suitable adhesive resin for the self-assembling anisotropic conductive adhesive, and through this, it is possible to see that the ratio of 1:1.2 or more and 1:1.5 or less is the optimal ratio.

### Experimental Example 2—Confirmation Experiment on Adhesion

In this Experimental Example 2, adhesion was tested using various self-assembling anisotropic conductive adhesives produced in Production Example 2.

The specific experimental method is as follows.
1.Used tool: UTM (Universal Testing Machine)
2.Used base material: PCB and FPCB adhesion (200 pitch)
3.Experiment conditions: Tensile speed 50 mm/min, 90° peel

Table 3 below summarizes the experimental results of Experimental Example 2.

TABLE 3

| Entry | Adhesion |
|---|---|
| 1 | X |
| 2 | X |
| 3 | X |
| 4 | Δ |
| 5 | Δ |
| 6 | Δ |
| 7 | Δ |
| 8 | ◯ |
| 9 | ◯ |
| 10 | ◯ |
| 11 | ◯ |
| 12 | ⊚ |
| 13 | ⊚ |
| 14 | ⊚ |
| 15 | ⊚ |
| 16 | ◯ |
| 17 | ◯ |
| 18 | Δ |
| 19 | Δ |
| 20 | x |

As seen from Table 3 above, the adhesion of 2.0-3.0 kgf/cm, which is the best adhesion, was shown in an SACA mixed with phenol novolac epoxy and bisphenol F epoxy in a ratio of 1:1.2 or more and 1:1.5 or less. Through this Experimental Example, it was possible to see that the best adhesion result was provided when phenol novolac epoxy and bisphenol F epoxy were mixed in a ratio of 1:1.2 or more and 1:1.5 or less.

### Experimental Example 3

In this Experimental Example 3, by using various self-assembling anisotropic conductive adhesives produced in Production Example 2, the surface resistance thereof was tested.

The specific experimental method is as follows.

As seen from the experimental results, the surface resistance was generally below 12, indicating that the result was excellent overall,

### Experimental Example 4

In this Experimental Example 4, an adhesive resin mixture was prepared by changing only the weight average molecular weight of the first epoxy resin in Production Example 1, a self-assembling anisotropic conductive adhesive containing the mixture was prepared, and an experiment was conducted to confirm the adhesion thereof.

The specific experimental method is as follows.
1.Used tool: UTM (Universal Testing Machine)
2.Used base material: PCB and FPCB adhesion (200 pitch)
3.Experiment conditions: Tensile speed 50 mm/min, 90° peel

TABLE 4

| | Weight average | |
|---|---|---|
| Entry | molecular weight | Adhesion |
| A | 1,000 | X |
| B | 5,000 | X |
| C | 10,000 | Δ |
| D | 20,000 | ◯ |
| E | 30,000 | ⊚ |
| F | 40,000 | ⊚ |
| G | 50,000 | ⊚ |
| H | 60,000 | ⊚ |
| I | 70,000 | Δ |
| J | 80,000 | X |
| K | 90,000 | X |
| L | 100,000 | X |

As seen from Table 4 above, in the case of the first epoxy resin, adhesion is most effective when the weight average molecular weight is 30,000 or more and 60,000 or less. This is because when the first epoxy resin having the above weight average molecular weight is used, the effect of low brittleness and high crosslinking density is provided.

### Experimental Example 5

In this Experimental Example 5, an adhesive resin mixture was prepared by changing only the epoxy equivalent of the second epoxy resin in Production Example 1, a self-assembling anisotropic conductive adhesive containing the mixture was prepared, and the properties thereof were tested.

The specific experimental method is as follows.
1.Used tool: UTM (Universal Testing Machine)
2.Used base material: PCB and FPCB adhesion (200 pitch)
3.Experiment conditions: Tensile speed 50 mm/min, 90° peel

TABLE 5

| Entry | Equivalent | Adhesion |
|---|---|---|
| I | 100 | ⊚ |
| II | 200 | ◯ |
| III | 300 | X |

As seen from Table 5 above, in the case of the second epoxy resin, the best effect is provided when the epoxy equivalent is 100 g/ep or more and 200 g/ep or less. This is because when the second epoxy resin having the above epoxy equivalent is used, the number of reactive epoxy groups is optimized, so that almost all of the epoxy groups participate in the reaction and none remain as impurities.

The description of the present invention described above is for illustrative purposes, and those skilled in the art will understand that the present invention is easily modifiable into other specific forms without changing the technical idea or essential features of the present invention. Therefore, the examples described above should be understood in all respects as illustrative and not restrictive. For example, each component described as single may be implemented in a distributed manner, and similarly, components described as distributed may also be implemented in a combined form.

The scope of the present invention is indicated by the claims described below, and all changes or modified forms derived from the meaning and scope of the claims and their equivalent concepts should be construed as being included in the scope of the present invention.

### EXPLANATION OF REFERENCE NUMERALS

10: Second substrate
11: Connection terminal
20: First substrate
21: Electrode terminal
30: Self-assembling anisotropic conductive adhesive
31: Solder particle
32: Adhesive resin included in adhesive resin mixture
33: Hardening agent
40: Connector
50: Hardened resin layer

1. A self-assembling anisotropic conductive adhesion adhesive resin mixture, comprising:
a first epoxy resin having a plurality of epoxy groups in a molecule; and
a second epoxy resin having a viscosity of 100 cps or more and 500 cps or less at 20° C. or more and 30° C. or less.

2. The self-assembling anisotropic conductive adhesion adhesive resin mixture of claim 1, wherein a weight ratio of the first epoxy resin and the second epoxy resin is 1:1.2 or more and 1:1.5 or less.

3. The self-assembling anisotropic conductive adhesion adhesive resin mixture of claim 1, wherein the adhesive resin mixture has a viscosity of 500 cps or more and 100,000 cps or less in a temperature range of 70° C. or more and 250° C. or less.

4. The self-assembling anisotropic conductive adhesion adhesive resin mixture of claim 1, wherein the first epoxy resin is one selected from a group consisting of a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin.

5. The self-assembling anisotropic conductive adhesion adhesive resin mixture of claim 3, wherein the first epoxy resin has a weight average molecular weight (Mw) of 30,000 or more and 60,000 or less.

6. The self-assembling anisotropic conductive adhesion adhesive resin mixture of claim 1, wherein the second epoxy resin is one selected from a group consisting of a bisphenol A type epoxy resin, bisphenol F type epoxy resin, bisphenol S type epoxy resin, bisphenol AF type epoxy resin, biphenyl type epoxy resin, naphthalene type epoxy resin, fluorene type epoxy resin, novolac type epoxy resin, phenol novolac type epoxy resin, orthocresol novolac type epoxy resin, glycidyl ether type epoxy resin, glycidyl amine type epoxy resin, cycloaliphatic type epoxy resin, aliphatic polyglycidyl type epoxy resin, epoxy resin modified with dimer acid, rubber modified epoxy resin, urethane modified epoxy resin, acrylic modified epoxy resin, and silicon modified epoxy resin.

7. The self-assembling anisotropic conductive adhesion adhesive resin mixture of claim 1, wherein the second epoxy resin has an epoxy equivalent of 10 g/ep or more and 200 g/ep or less.

8. A self-assembling anisotropic conductive adhesive having controlled fluidity, comprising:
conductive solder particles; and
the adhesive resin mixture of claim 1,
wherein by having the adhesive resin mixture to have a viscosity of 500 cps or more and 100,000 cps or less in a temperature range of 70° C. or more and 250° C. or less, the solder particles and the adhesive resin mixture are positioned maximally between metal terminals of a substrate during a component mounting process.

9. The self-assembling anisotropic conductive adhesive having controlled fluidity of claim 8, wherein the solder particles have a melting point between a reaction initiation temperature and a hardening temperature of the conductive adhesive resin mixture.

10. The self-assembling anisotropic conductive adhesive having controlled fluidity of claim 8, wherein the solder particles comprise at least one selected from the a group consisting of tin (Sn), copper (Cu), indium (In), silver (Ag), and bismuth (Bi).

11. The self-assembling anisotropic conductive adhesive having controlled fluidity of claim 8, wherein the solder particles have a melting point of 70° C. or more and 250° C. or less.

12. The self-assembling anisotropic conductive adhesive having controlled fluidity of claim 8, wherein the anisotropic conductive adhesive is in the a form of a film or paste.
